(19) United States
(12) Patent Application Publication
(10) Pub. No.: US 2024/0324219 A1
(43) Pub. Date: Sep. 26, 2024

(54) INTEGRATED CIRCUIT DEVICES

(71) Applicant: SAMSUNG ELECTRONICS CO., LTD., Suwon-si (KR)

(72) Inventors: Choasub KIM, Suwon-si (KR); Chungjin KIM, Suwon-si (KR); Youngho KWON, Suwon-si (KR); Jungho LEE, Suwon-si (KR)

(21) Appl. No.: 18/604,844

(22) Filed: Mar. 14, 2024

(30) Foreign Application Priority Data
Mar. 24, 2023 (KR) 10-2023-0038954
May 4, 2023 (KR) 10-2023-0058497

(51) Int. Cl. H10B 43/27

(52) U.S. Cl. CPC H10B 43/27

(57) ABSTRACT

An integrated circuit device comprising: a substrate; a stack structure comprising interlayer insulating layers and gate electrodes; and a channel structure in the stack structure, wherein the gate electrodes comprise a first upper gate electrode at a highest position and a second upper gate electrode at a second-highest position, the interlayer insulating layers comprises a first interlayer insulating layer between the first upper gate electrode and the second upper gate electrode with a first thickness, a second interlayer insulating layer that has a second thickness, a lower surface of the first upper gate electrode is at a farther distance than or at an equal distance to a lower surface of the pad structure from the substrate, and an upper surface of the second upper gate electrode is at a closer distance than or at an equal distance to the lower surface of the pad structure from the substrate.

### CROSS-REFERENCE TO RELATED APPLICATIONS

This application is based on and claims priority under 35 U.S.C. § 119 to Korean Patent Application Nos. 10-2023-0038954 and 10-2023-0058497, filed on Mar. 24, 2023 and May 4, 2023, respectively, in the Korean Intellectual Property Office, the disclosures of which are incorporated by reference herein in their entireties.

### BACKGROUND

The inventive concept relates to integrated circuit devices. More particularly, the inventive concept relates to integrated circuit devices including a nonvolatile vertical memory device.

According to the development of electronics technology, down-scaling of integrated circuit devices have been rapidly performed. Integrated circuit devices, with continuous decrease in size, require high-capacitance data processing. Accordingly, there is requirement for the increase in the integration of semiconductor devices included in integrated circuit devices. Therefore, as one of the methods of improving the integration of integrated circuit devices, integrated circuit devices having a vertical transistor structure have been suggested.

### SUMMARY

The inventive concept may provide an integrated circuit device in which a thickness in a vertical direction of a first interlayer insulating layer arranged under a first upper gate electrode is greater than a thickness in the vertical direction of another interlayer insulating layer.

The inventive concept may provide an integrated circuit device in which an erase gate electrode arranged at a highest position of the gate electrodes horizontally overlaps a pad structure arranged on channel structures.

According to an aspect of the inventive concept, there is provided an integrated circuit device comprising: a substrate; a stack structure comprising interlayer insulating layers and gate electrodes stacked alternately with the interlayer insulating layers on the substrate; a channel structure comprising a core pattern, a pad structure on the core pattern, and a channel layer on a side surface of the core pattern and a side surface of the pad structure, wherein the channel structure is in the stack structure; a plug on the channel structure; and a bit line on the plug, wherein the gate electrodes comprise a first upper gate electrode at a highest position among the gate electrodes relative to the substrate and a second upper gate electrode at a second-highest position among the gate electrodes relative to the substrate, the second upper gate electrode is directly adjacent to the first upper gate electrode in a vertical direction perpendicular to an upper surface of the substrate, the interlayer insulating layers comprises a first interlayer insulating layer that is between the first upper gate electrode and the second upper gate electrode and has a first thickness in the vertical direction, the first thickness is different from a second thickness of a second interlayer insulating layer of the interlayer insulating layers in the vertical direction, and a lower surface of the pad structure is distant from the substrate by a first distance, a lower surface of the first upper gate electrode is distant from the substrate by a second distance that is longer than or equal to the first distance, and an upper surface of the second upper gate electrode is distant from the substrate by a third distance that is shorter than or equal to the first distance.

According to another aspect of the inventive concept, there is provided an integrated circuit device comprising: a substrate; a stack structure comprising interlayer insulating layers and gate electrodes stacked alternately with the interlayer insulating layers on the substrate; a channel structure in the stack structure; a plug on the channel structure; and a bit line on the plug, wherein the channel structure comprises a core pattern, a pad structure on the core pattern, and a channel layer on a side surface of the core pattern and a side surface of the pad structure, a first upper gate electrode at a highest position among the gate electrodes relative to the substrate comprises an erase gate electrode, a first thickness in a vertical direction of a first interlayer insulating layer of the interlayer insulating layers is different from a second thickness in the vertical direction of a second interlayer insulating layer of the interlayer insulating layers, the first interlayer insulating layer is between the first upper gate electrode and the second interlayer insulating layer, and the vertical direction is perpendicular to an upper surface of the substrate.

According to another aspect of the inventive concept, there is provided an integrated circuit device comprising: a first substrate; circuit devices on the first substrate; a second substrate on the circuit devices; a stack structure comprising interlayer insulating layers and gate electrodes stacked alternately with the interlayer insulating layers on the second substrate in a vertical direction perpendicular to an upper surface of the second substrate; and a channel structure in the stack structure, the channel structure comprising a channel layer, a core pattern on a side surface of the channel layer, and a pad structure on the core pattern, wherein the gate electrodes comprise a first upper gate electrode at a highest position among the gate electrodes relative to the second substrate and a second upper gate electrode at a second-highest position among the gate electrodes relative to the second substrate, a first thickness of a first interlayer insulating layer of the interlayer insulating layers in the vertical direction is different from a second thickness of a second interlayer insulating layer of the interlayer insulating layers in the vertical direction, the first interlayer insulating layer is between the first upper gate electrode and the second upper gate electrode, and a lower surface of the pad structure is distant from the second substrate by a first distance, a lower surface of the first upper gate electrode is distant from the second substrate by a second distance that is longer than or equal to the first distance, and an upper surface of the second upper gate electrode is distant from the second substrate by a third distance that is shorter than or equal to the first distance.

### BRIEF DESCRIPTION OF THE DRAWINGS

Embodiments will be more clearly understood from the following detailed description taken in conjunction with the accompanying drawings in which:

FIG. 1 is a block diagram illustrating an integrated circuit device according to some embodiments of the inventive concept;

FIG. 2 is a circuit diagram illustrating an example of a memory block according to some embodiments of the inventive concept;

FIG. 3 is a cross-sectional view schematically illustrating an integrated circuit device according to some embodiments of the inventive concept;

FIG. 4 is an enlarged view of a portion of an integrated circuit device according to some embodiments of the inventive concept;

FIG. 5 is a cross-sectional view schematically illustrating an integrated circuit device according to some embodiments of the inventive concept;

FIG. 6 is a cross-sectional view schematically illustrating an integrated circuit device according to some embodiments of the inventive concept;

FIG. 7 is a cross-sectional view schematically illustrating an integrated circuit device according to some embodiments of the inventive concept;

FIGS. 8A to 8E are cross-sectional views for describing a method of manufacturing an integrated circuit device, according to some embodiments of the inventive concept;

FIG. 9 is a diagram schematically illustrating a data storage system including an integrated circuit device according to some embodiments of the inventive concept;

FIG. 10 is a perspective view schematically illustrating a data storage system including an integrated circuit according to some embodiments of the inventive concept; and

FIG. 11 is a cross-sectional view schematically illustrating semiconductor packages according to some embodiments of the inventive concept.

### DETAILED DESCRIPTION OF THE EMBODIMENTS

Hereinafter, embodiments of the inventive concept will be described in detail with reference to the accompanying drawings. Same reference numerals may be used for same components in the drawings, and same descriptions thereof may not be repeatedly given.

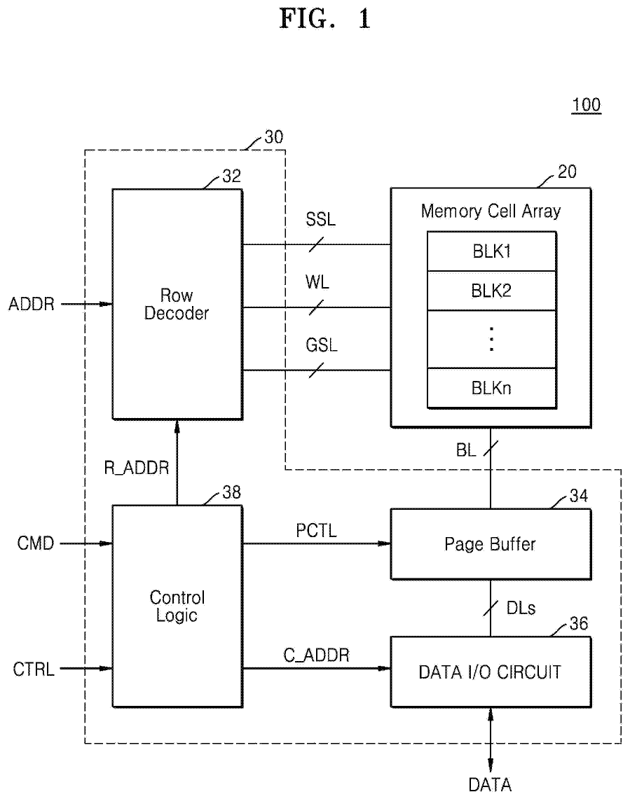

FIG. 1 is a block diagram illustrating an integrated circuit device 100 according to some embodiments of the inventive concept.

Referring to FIG. 1, the integrated circuit device 100 may include a memory cell array 20 and a peripheral circuit 30.

The memory cell array 20 may include a plurality of memory cell blocks BLK1, BLK2, . . . , BLKn. The plurality of memory cell blocks BLK1, BLK2, . . . , BLKn may each include a plurality of memory cells. The plurality of memory cell blocks BLK1, BLK2, . . . , BLKn may be connected to the peripheral circuit 30 through a bit line BL, a word line WL, a string selection line SSL, and a ground selection line GSL. Hereinafter, a “connection” may refer to a “physical connection” and/or an “electrical connection”.

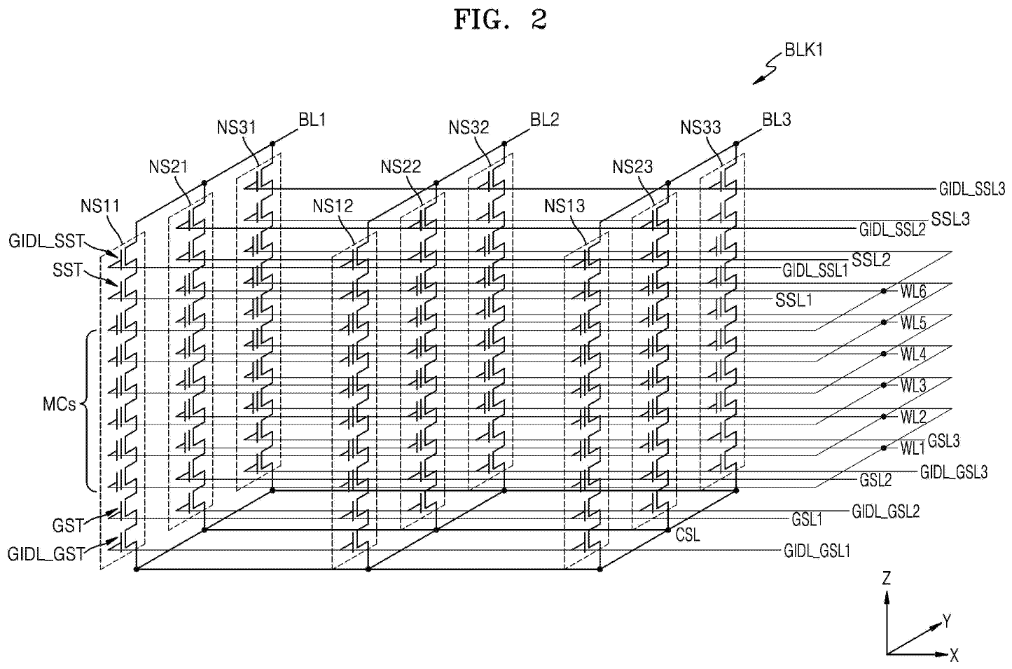

In addition, as shown in FIG. 2, the plurality of memory cell blocks BLK1, BLK2, . . . , BLKn may be connected to a plurality of gate-induced drain leakage (GIDL) string selection lines GIDL_SSL1, GIDL_SSL2, and GIDL_SSL3, a plurality of GIDL ground selection lines GIDL_GSL1, GIDL_GSL2, and GIDL_GSL3, and a plurality of word lines WL1, WL2, WL3, WL4, WL5, and WL6.

The memory cell array 20 may be connected to a page buffer 34 through the bit line BL and may be connected to a row decoder 32 through the word line WL, the string selection line SSL, and the ground selection line GSL. In the memory cell array 20, the plurality of memory cells included in the plurality of memory cells BLK1, BLK2, . . . , BLKn may each include a flash memory cell. The memory cell array 20 may include a three-dimensional memory cell array. The three-dimensional memory cell array may include a plurality of NAND strings, and the plurality of NAND strings may include a plurality of memory cells respectively connected to a plurality of word lines WL vertically stacked.

The peripheral circuit 30 may include the row decoder 32, the page buffer 34, a data input/output circuit 36, and a control logic 38. Although not shown, the peripheral circuit 30 may further include various circuits such as a voltage generation circuit configured to generate various voltages for operation of the integrated circuit device 10, an error correction circuit configured to correct errors of data read from the memory cell array 20, and an input/output interface.

The peripheral circuit 30 may be configured to receive an address ADDR, a command CMD, and a control signal CTRL from outside the integrated circuit device 10 and transmit/receive data DATA to/from a device outside the integrated circuit device 10. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device. A detailed configuration of the peripheral circuit 30 is as follows.

The row decoder 32 may be configured to select at least one of the plurality of memory cell blocks BLK1, BLK2, . . . , BLKn, in response to the address ADDR from outside the integrated circuit device 10 and may also be configured to select the word line WL, the string selection line SSL, the ground selection line GSL of the memory cell block that has been selected. The row decoder 32 may be configured to deliver a voltage for performance of a memory operation to the word line WL of the memory cell block that has been selected.

The page buffer 34 may be connected to the memory cell array 20 through the bit line BL. In a program operation, the page buffer 34 may be configured to operate as a write driver and apply, to the bit line BL, a voltage according to the data DATA to be stored in the memory cell array 20, and in a read operation, the page buffer 34 may be configured to operate as a sensing amplifier and sense the data DATA stored in the memory cell array 20. The page buffer 34 may be configured to operate in response to a control signal PCTL provided from the control logic 38.

The data input/output circuit 36 may be connected to the page buffer 34 through data lines DLs. The data input/output circuit 36 may be configured to receive the data DATA from a memory controller (not shown) in the program operation and provide program data DATA to the page buffer 34, based on a column address C_ADDR provided from the control logic 38. In the read operation, the data input/output circuit 36 may be configured to provide read data DATA stored in the page buffer 34 to the memory controller, based on the column address C_ADDR provided from the control logic 38. The data input/output circuit 36 may be configured to deliver an address or instruction, which are input, to the control logic 38 or the row decoder 32.

The control logic 38 may be configured to receive the command CMD and the control signal CTRL from the memory controller. The control logic 38 may be configured to provide a row address R_ADDR to the row decoder 32 and provide the column address C_ADDR to the data input/output circuit 36. The control logic 38 may be configured to generate various internal control signals used in the integrated circuit device 100, in response to the control signal CTRL. For example, during performance of memory operations such as the program operation or an erase operation, the control logic 38 may be configured to adjust a level of a voltage provided to the word line WL and the bit line BL.

FIG. 2 is a circuit diagram illustrating an example of a memory block BLK1 according to some embodiments of the inventive concept.

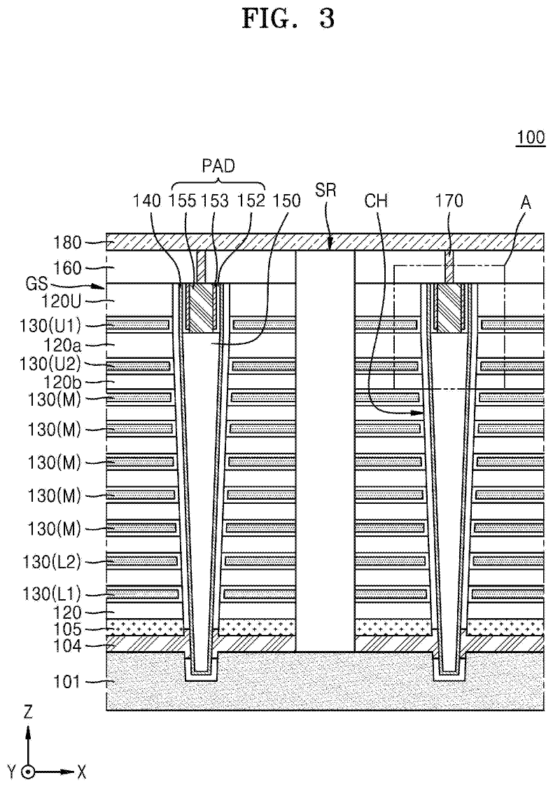

The memory block shown in FIG. 2 is an example of the plurality of memory blocks BLK1, BLK2, . . . , BLKn described with reference to FIG. 1 and is illustrated as the first memory block BLK1. The first memory block BLK1 may be a three-dimensional memory block formed into a three-dimensional structure on a substrate. A plurality of memory cell strings included in the first memory block BLK1 may be formed in a direction perpendicular (a Z direction) to the substrate (e.g., an upper surface of a substrate 101 in FIG. 3).

Referring to FIG. 2, the first memory blocks BLK1 may include a plurality of cell strings NS11 to NS33 (e.g., NS11, NS21, NS31, NS12, NS22, NS32, NS13, NS23, and NS33), a plurality of word lines WL1, WL2, WL3, WL4, WL5, and WL6, a plurality of bit lines BL1, BL2, and BL3, the plurality of GIDL ground selection lines GIDL_GSL1, GIDL_GSL2, and GIDL_GSL3, a plurality of ground selection lines GSL1, GSL2, and GSL3, a plurality of GIDL string selection lines GIDL_SSL1, GIDL_SSL2, and GIDL_SSL3, string selection lines SSL1, SSL2, and SSL3, and a common source line CSL. Although FIG. 2 illustrates that each of the plurality of cell strings NS11 to NS33 includes six memory cells MCs connected to the word lines WL1, WL2, WL3, WL4, WL5, and WL6, the inventive concept is not limited thereto.

Each of the cell strings (e.g., the cell string NS11) may include a GIDL string selection transistor GIDL_SST, a string selection transistor SST, the plurality of memory cells MCs, a GIDL ground selection transistor GIDL_GST, and a ground selection transistor GST connected in series. The GIDL string selection transistor GIDL_SST may be connected to the GIDL string selection line GIDL_SSL1 corresponding thereto, and the string selection transistor SST may be connected to the string selection line SSL1 corresponding thereto. The plurality of memory cells MCs may each include a plurality of memory cell transistors and be connected to the word lines WL1, WL2, WL3, WL4, WL5, and WL6 corresponding to the plurality of memory cells MCs. The GIDL ground selection transistor GIDL_GST may be connected to the GIDL ground selection line GIDL_GSL1 corresponding thereto, and the ground selection transistor GST may be connected to the ground selection line GSL1 corresponding thereto. The GIDL string selection transistor GIDL_SST may be connected to a bit line (e.g., the bit line BL1) corresponding thereto, and the GIDL ground selection transistor GIDL_GST may be connected to the common source line CSL.

In the cell strings NS11 to NS33, a word line (e.g., the word line WL1) at a same height may be connected to the cell strings NS11 to NS33 in common, and the GIDL ground selection lines GIDL_GSL1, GIDL_GSL2, and GIDL_GSL3, the ground selection lines GSL1, GSL2, and GSL3, the GIDL string selection lines GIDL_SSL1, GIDL_SSL2, and GIDL_SSL3, and the string selection lines SSL1, SSL2, and SSL3 may be separated from one another. Generally, the GIDL ground selection lines GIDL_GSL1, GIDL_GSL2, GIDL_GSL3, the ground selection lines GSL1, GSL2, and GSL3 may be configured in a block unit, unlike the GIDL string selection lines GIDL_SSL1, GIDL_SSL2, and GIDL_SSL3 and the string selection lines SSL1, SSL2, and SSL3, but may be additionally separated for improvement of the performance thereof. The height hereinafter may refer to a distance in the Z direction from a lower surface of a substrate (e.g., the substrate 101 in FIG. 3).

In some embodiments, each of the GIDL string selection transistor GIDL_SST, the string selection transistor SST, the GIDL ground selection transistor GIDL_GST, and the ground selection transistor GST may be provided in a singularity or a plurality.

An erase operation to erase data stored in the memory cell transistors may be performed using the GIDL effect occurring in the GIDL string selection transistor GIDL_SST and the GIDL ground selection transistor GIDL_GST. In the erase operation, a first voltage, i.e., an erase voltage, may be applied to the bit line BL, and a second voltage less than the first voltage may be applied to erase gate electrodes of the GIDL string selection lines GIDL_SSL1, GIDL_SSL2, and GIDL_SSL3. For example, holes generated due to the GIDL effect in the GIDL string selection transistor GIDL_SST and the GIDL ground selection transistor GIDL_GST may be injected into channels of the memory cell transistors, and the data in the memory cell transistors may be erased due to the holes injected into the channels of the memory cell transistors (e.g., the plurality of memory cells MCs). For example, the holes injected into the channels of the memory cell transistors may allow electrons, which are trapped in data storage layers of the memory cell transistors, to escape through the channels of the memory cell transistors.

FIG. 3 is a cross-sectional view schematically illustrating the integrated circuit device 100 according to some embodiments of the inventive concept.

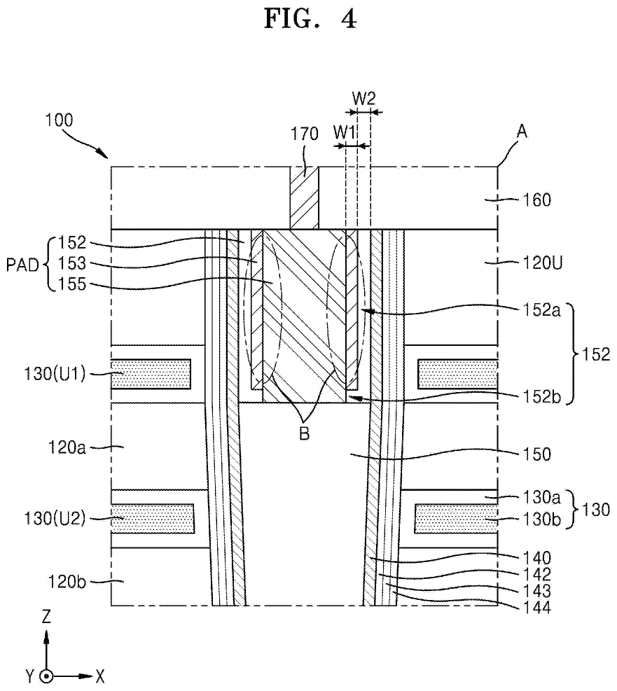

FIG. 4 is an enlarged view of a portion of the integrated circuit device 100 according to some embodiments of the inventive concept.

FIG. 4 illustrates an enlarged image of a region A shown in FIG. 3. Referring to FIGS. 3 and 4, the integrated circuit device 100 may include a substrate 101, a stack structure GS on the substrate 101, and a separation region SR. The stack structure GS may include a plurality of interlayer insulating layer 120 and a plurality of gate electrodes 130. The plurality of interlayer insulating layers 120 may be alternately and repeatedly stacked with the plurality of gate electrodes 130 in a vertical direction (the Z direction) on the substrate 101. For example, the interlayer insulating layers 120 may be alternately and repeatedly stacked with the plurality of gate electrodes 130 in the Z direction. A plurality of channel structures CH may extend in (e.g., penetrate) the stack structure GS in the Z direction. The separation region SR may extend in (e.g., penetrate) the stack structure GS in the Z direction and extend in a horizontal direction parallel with an upper surface of the substrate 101 (e.g., an X direction or a Y direction). The horizontal direction may be perpendicular to the vertical direction. The integrated circuit device 100 may further include a first conductive pattern 104 and a second conductive pattern 105 arranged between the substrate 101 and the stack structure GS. The integrated circuit device 100 may further include an upper insulating layer 160 on the stack structure GS, a plurality of contact plugs 170 electrically connected to the channel structures CH, and a bit line 180 electrically connected to the plurality of contact plugs 170 on the plurality of contact plugs 170. The plurality of contact plugs 170 may extend in the upper insulating layer 160 in the Z direction.

The substrate 101 may have the upper surface extending in the first horizontal direction (the X direction) and the second horizontal direction (the Y direction). The substrate 101 may include a semiconductor material, e.g., a Group IV semiconductor, a Group III-V compound semiconductor, or a Group II-IV compound semiconductor. For example, the Group IV semiconductor may include silicon, germanium, or silicon-germanium. The substrate 101 may also be provided in the form of a bulk wafer, an epitaxial layer, a silicon-on-insulator (SOI) layer, or a semiconductor-on-insulator (SeOI) layer.

The interlayer insulating layers 120 may include an insulating material such as silicon oxide or silicon nitride. Among the interlayer insulating layers 120, an uppermost interlayer insulating layer 120U may have a thickness in the Z direction that is greater than a thickness of each of other interlayer insulating layers 120 in the Z direction.

The gate electrodes 130 may be stacked apart from one another in the vertical direction (the Z direction) on the substrate 101. The gate electrodes 130 may extend to different lengths in a horizontal direction (e.g., the X direction or the Y direction) in at least one region on the substrate 101.

The gate electrodes 130 may include one or more lower gate electrodes 130(L1) and 130(L2), a plurality of middle gate electrodes 130(M) arranged above (on) the one or more lower gate electrodes 130(L1) and 130(L2), and one or more upper gate electrodes 130(U1) and 130(U2) arranged above (on) the plurality of middle gate electrodes 130(M).

The one or more lower gate electrodes 130(L1) and 130(L2) may include a first lower gate electrode 130(L1) and a second lower gate electrode 130(L2) above (on) the first lower gate electrode 130(L1). The first lower gate electrode 130(L1) and the second lower gate electrode 130(L2) may respectively correspond to the GIDL ground selection line GIDL_GSL1 and the ground selection line GSL1 described with reference to FIG. 2. The first lower gate electrode 130(L1), as a lower erase gate electrode, may be at a lowermost portion of the plurality of gate electrodes 130. The first lower gate electrode 130(L1) may overlap a side surface of a core pattern 150 in a horizontal direction (e.g., the X direction). A side surface of the first lower gate electrode 130(L1) may face the side surface of the core pattern 150 and a side surface of a channel layer 140.

The one or more upper gate electrodes 130(U1) and 130(U2) may include a first upper gate electrode 130(U1) and a second upper gate electrode 130(U2). The first upper gate electrode 130(U1) may be disposed on the second upper gate electrode 130(U2). The first upper gate electrode 130(U1), as an upper erase gate electrode, may be at an uppermost position of the plurality of gate electrodes 130. The first upper gate electrode 130(U1) and the second upper gate electrode 130(U2) may respectively correspond to the GIDL string selection line GIDL_SSL1 and the string selection line SSL1 described with reference to FIG. 2. In some embodiment, the first upper gate electrode 130(U1) may overlap a pad structure PAD in the first horizontal direction (the X direction). In some embodiments, a side surface of the first upper gate electrode 130(U1) may face a side surface of the pad structure PAD.

In some embodiments, a sum of thicknesses in the vertical direction (the Z direction) of the first upper gate electrode 130(U1) at the uppermost position of the gate electrodes 130 and a first interlayer insulating layer 120a (e.g., a second-highest interlayer insulating layer among the plurality of interlayer insulating layers 120) under the first upper gate electrode 130(U1) may be different from a sum of thicknesses in the vertical direction of another gate electrode among the plurality of gate electrodes 130 and another interlayer insulating layer (e.g., (directly) adjacent to the another gate electrode) among the plurality of gate electrodes 130. Particularly, the thickness of the first interlayer insulating layer 120a in the vertical direction (the Z direction) may be greater than a thickness of another interlayer insulating layer (120b or 120) in the vertical direction (the Z direction). The other interlayer insulating layers 120b and 120 may refer to interlayer insulating layers lower than the first interlayer insulating layer 120a in the vertical direction among the plurality of interlayer insulating layers 120. For example, the thickness in the vertical direction (the Z direction) of the first interlayer insulating layer 120a may be in a range from about 380 angstroms (Å) to about 500 Å. It will be understood that the term “directly adjacent to” as used herein includes configurations where two “elements” which are said to be directly adjacent to one another are positioned so that no other like element is located between the two elements which are said to be directly adjacent to one another.

In some embodiments, the thickness in the vertical direction (the Z direction) of the first upper gate electrode 130(U1) may be different from a thickness in the vertical direction (the Z direction) of each of other gate electrodes (i.e., the second upper gate electrode 130(U2), the middle gate electrode 130(M), the first lower gate electrode 130(L1), or the second lower gate electrode 130(L2)) among the plurality of the first upper gate electrodes 130. In addition, the number of first upper gate electrodes 130U1 may be variously modified according to some embodiments.

The middle gate electrodes 130M may be arranged between one or more of the lower gate electrodes 130(L1) and 130(L2) and one or more of the upper gate electrodes 130(U1) and 130(U2). At least some of the middle gate electrodes 130M may correspond to the word lines WL described with reference to FIG. 2. From among the middle gate electrodes 130(M), the middle gate electrodes 130(M) adjacent to the one or more lower gate electrodes 130(L1) and 130(L2) or the one or more upper gate electrodes 130(U1) and 130(U2) may include dummy gate electrodes. The number of middle gate electrodes 130M may be determined according to a storage capacity of the integrated circuit device 100.

The gate electrodes 130 may be arranged in separation into a certain unit by the separation regions SR extending in a direction (e.g., in the Z direction and the Y direction). The gate electrodes 130 between two separation regions SR may together form a memory block, but a range of the memory block is not limited thereto.

Each of the gate electrodes 130 may include a first gate layer 130a and a second gate layer 130b. The first gate layers 130a may include, for example, tungsten nitride WN, tantalum nitride TaN, titanium nitride TiN, or a combination thereof. The second gate layers 130b may include a metal material, e.g., tungsten (W). According to some embodiments, the gate electrodes 130 may include polysilicon or a metal silicide material.

In some embodiments, each of the first gate layers 130a may be formed into a dielectric layer, e.g., a high-k dielectric layer, and each of the second gate electrodes 130b may be formed into a gate electrode.

The channel structures CH may be arranged apart from one another in rows and columns on the substrate 101. The channel structures CH may be arranged in a grid or a zigzag shape in a direction. The channel structures CH may extend in a vertical direction on/in the substrate 101. The channel structures CH may have a pillar shape and may also have inclined side surfaces having widths in the horizontal direction (e.g., the X direction and/or the Y direction) decreasing toward the substrate 101 according to an aspect ratio.

The channel structures CH may each include the core pattern 150, the pad structure PAD arranged on the core pattern 150, and the channel layer 140 arranged on the side surface of the core pattern 150 and the side surface of the pad structure PAD.

In the channel structures CH, the channel layer 140 may be formed into an annular shape extending around (e.g., surrounding) the core patterns 150. However, according to some embodiments, the channel structure CH may include the channel layer 140 that is in a pillar shape such as a cylinder or a prism, without the core pattern 150.

In some embodiments, the channel layer 140 may directly contact the first conductive pattern 104. The channel layer 140 may be electrically connected to the substrate 101 through the first conductive pattern 104 at a lower portion of the channel layer 140.

The channel layer 140 may include a semiconductor material such as polycrystalline material, and the semiconductor material may include an undoped material or a p-type or n-type semiconductor material. The channel structures CH arranged on a straight line in the first horizontal direction (the X direction) may be respectively connected to different bit lines 180 by the contact plugs 170 connected to the pad structure PAD, according to the arrangement of the upper wiring structure. In addition, some of the channel structures CH may include dummy channels not connected to the bit line 180.

As shown in FIG. 4, each of the channel structures CH may include a tunneling layer 142, a charge storage layer 143, and a blocking layer 144 sequentially arranged from (on) the channel layer 140. For example, the tunneling layer 142, the charge storage layer 143, and the blocking layer 144 may be between the channel layer 140 and the gate electrodes 130 and/or between the channel layer 140 and the interlayer insulating layers 120. Relative thicknesses of the tunneling layer 142, the charge storage layer 143, and the blocking layer 144 are not limited to the illustration in the schematic diagram and may be variously modified in embodiments.

The tunneling layer 142 may include, for example, silicon oxide (SiO₂), silicon oxynitride (SiON), or a combination thereof. The charge storage layer 143 may include a charge trapping layer and may include silicon nitride. The blocking layer 144 may include SiO₂, SiON, a high-k dielectric material, or a combination thereof.

In the channel structures CH, the tunneling layers 142, the charge storage layers 143, and the blocking layers 114 may be arranged to extend into the substrate 101. The tunneling layers 142, the charge storage layers 143, and the blocking layer 144 may be partially removed at lower portions thereof, and in a region from which the tunneling layers 142, the charge storage layers 143, and the blocking layers 144 have been removed, the channel layer 140 may be connected to the first conductive pattern 104.

The pad structure PAD may be on (e.g., arranged to at least partially cover) an upper surface of the core pattern 150 and electrically connected to the channel layer 140. The pad structure PAD may include a pad pattern 155, a first pad layer 153, and a second pad layer 152. The pad pattern 155 may be disposed on the core pattern 150. The first pad layer 153 and the second pad layer 152 may be disposed between the channel layer 140 and the pad pattern 155. A first surface corresponding to a side surface of the first pad layer 153 may contact the side surface of the pad pattern 155. A second surface of the first pad layer 153, which is opposite to the first surface, and a lower surface of the first pad layer 153 may be surrounded (e.g., covered) by the second pad layer 152. That is, the first pad layer 153 may be arranged on the second pad layer 152. The second pad layer 152, as a buffer pad, may include a first portion 152a disposed between the channel layer 140 and the first pad layer 153 and a second portion 152b disposed between the first pad layer 153 and the core pattern 150. A surface of the first portion 152a may contact the first pad layer 153. A surface of the second portion 152b may contact the pad pattern 155. Another surface of each of the first portion 152a and the second portion 152b may contact the channel layer 140. A lower surface of the second portion 152b may contact an upper surface of the core pattern 150. The first portion 152a and the second portion 152b may have substantially same thicknesses but are not limited thereto. In some embodiments, the first portion 152a and the second portion 152b may have different thicknesses. In some embodiments, the second pad layer 152 may have the form of the letter “L” in a cross-sectional view.

A thickness W2 of the second pad layer 152 in a horizontal direction (e.g., the X direction) may be greater than a thickness W1 of the first pad layer 153 in the horizontal direction. In some embodiments, the thickness W1 of the first pad layer 153 may be in a range from about 4.5 nanometers (nm) to about 5.5 nm. In some embodiments, the thickness W2 of the second pad layer 152 may be in a range from about 8 nm to about 15 nm. In some embodiments, the thickness W2 of the second pad layer 152 may be in a range from about 8 nm to about 9 nm.

The pad pattern 155 may include a semiconductor material, e.g., a doped polycrystalline silicon. The pad pattern 155 may be doped with a first impurity and have a first conductive type. In some embodiments, the first impurity may include a Group V element in the periodic table, e.g., phosphorous (P) or arsenic (As). Accordingly, the pad pattern 155 may have a conductive type of N-type. For example, when the pad pattern 155 is doped with P or As, the concentration of P or As may be in a range from about 2×10²⁰/cm³ to about 3×10²⁰/cm³.

The first pad layer 153 may include a semiconductor material, e.g., doped polycrystalline silicon. The first pad layer 153 may have a second conductive type that is different from the first conductive type. The first pad layer 153 may be doped with a second impurity that is different from the first impurity and have a second conductive type. In some embodiments, the second impurity may include a Group III element in the periodic table, e.g., boron (B). Accordingly, the first pad layer 153 may have a conductive type of P-type. In some embodiments, when the first pad layer 153 is doped with B, the concentration of B may be in a range from about 1×10²⁰/cm³ to about 1.5×10²⁰/cm³.

The second pad layer 152 may include a semiconductor material such as polycrystalline silicon, and the semiconductor material may include an undoped material. The second pad layer 152 may include a buffer pad.

A contact region B may be defined as a portion in which a side surface of the pad pattern 155 having the first conductive type and the first surface of the first pad layer 153 having the second conductive type contact each other. In the erase operation, the GIDL effect described with reference to FIG. 2 may be induced in the contact region B of the pad structure PAD, and therefore, electron-hole pairs may be formed in the entire portion or a portion of the contact region B.

The separation region SR may extend in (e.g., penetrate) the stack structure GS in the vertical direction. The separation region SR may extend in the second horizontal direction (the Y direction). The separation region SR may include an insulating material, e.g., silicon oxide.

The first conductive pattern 104 and the second conductive pattern 105 may be stacked on the upper surface of the substrate 101. At least a portion of the first conductive pattern 104 and the second conductive pattern 105 may function as the common source line CSL of the integrated circuit device 100. The first conductive pattern 104 may be directly connected to the channel layer 140 at circumferences of the channel structures CH. The first conductive pattern 104 and the second conductive pattern 105 may include a semiconductor material, e.g., polycrystalline silicon. In this case, at least the first conductive pattern 104 may include a doped layer, and the second conductive pattern 105 may include a doped layer or a layer including the impurities diffused from the first conductive pattern 104.

The upper insulating layer 160 may be arranged on the uppermost interlayer insulating layer 120U. The upper insulating layer 160 may include an insulating material such as silicon oxide.

The contact plugs 170 may extend in (e.g., penetrate) the upper insulating layer 160 and be electrically connected to the channel structures CH. For example, the contact plugs 170 may contact the pad patterns 155 of the channel structures CH (e.g., the pad structure PAD).

The bit line 180 may be arranged on the upper insulating layer 160. The bit line 180 may contact the contact plugs 170 and be electrically connected to the channel structures CH through the contact plugs 170. The bit line 180 may correspond to the bit line BL described with reference to FIG. 2.

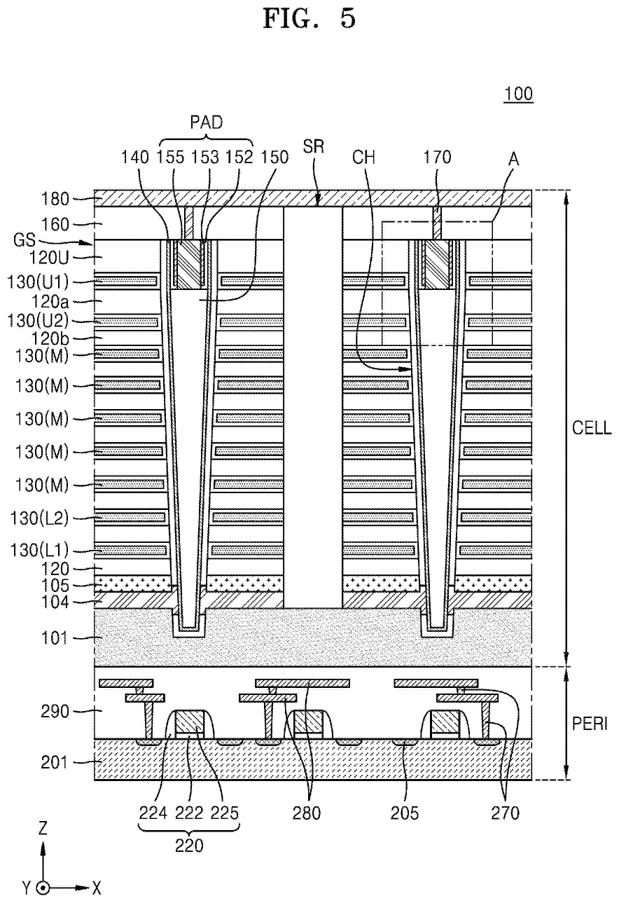

FIG. 5 is a cross-sectional view schematically illustrating the integrated circuit device 100 according to some embodiments of the inventive concept.

Referring to FIG. 5, the integrated circuit device 100 may include a memory cell region CELL and a peripheral circuit region PERI stacked in the vertical direction. The memory cell region CELL may be arranged on an upper surface of the peripheral circuit region PERI. However, the memory cell region CELL is not limited thereto and, in example embodiments, may also be arranged on a lower surface of the peripheral circuit region PERI.

The peripheral circuit region PERI may include a base substrate 201, circuit devices 220 arranged on the base substrate 201, circuit contact plugs 270, and circuit wiring lines 280.

The base substrate 201 may have an upper surface extending in the first horizontal direction (the X direction) and the second horizontal direction (the Y direction). Additional device isolation layers may be formed to define an active region in the base substrate 201. Source/drain regions 205 including impurities may be arranged in a portion of the active region. The base substrate 201 may include a semiconductor material, e.g., a Group IV semiconductor, a Group III-V compound semiconductor, or a Group II-VI compound semiconductor.

The circuit devices 220 may each include a horizontal transistor. Each of the circuit devices 220 may include a circuit gate dielectric layer 222, a spacer layer 224, and a circuit gate electrode 225. At two sides of the circuit gate electrode 225, the source/drain regions 205 may be arranged in the base substrate 201.

A peripheral region insulating layer 290 may be disposed on the circuit devices 220 and on the base substrate 201. The circuit contact plugs 270 may extend in (e.g., at least partially penetrate) the peripheral region insulating layer 290 and be connected to the source/drain regions 205. Electrical signals may be applied to the circuit devices 220 by the circuit contact plugs 270. In a region that is not shown, the circuit contact plugs 270 may also be connected to the circuit gate electrode 225. The circuit wiring lines 280 may be connected to the circuit contact plugs 270 and may be arranged in the form of a plurality of layers.

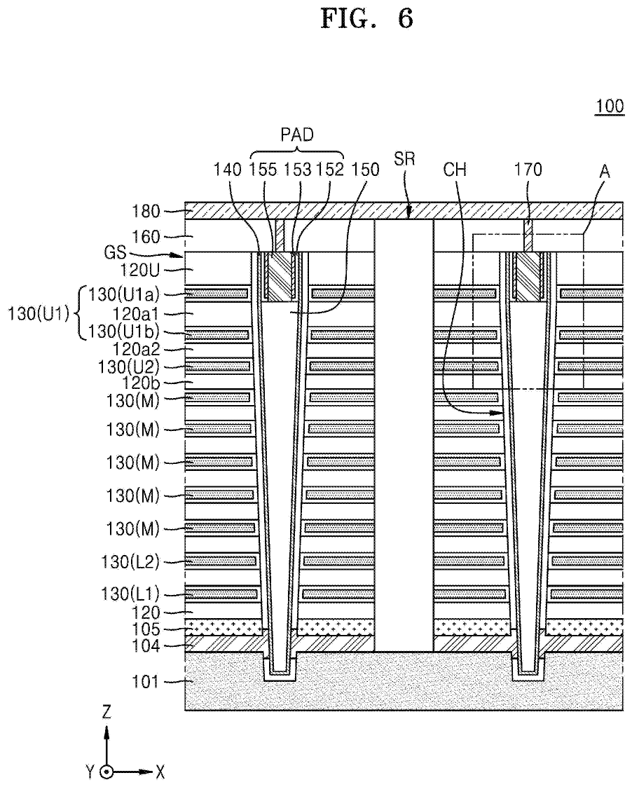

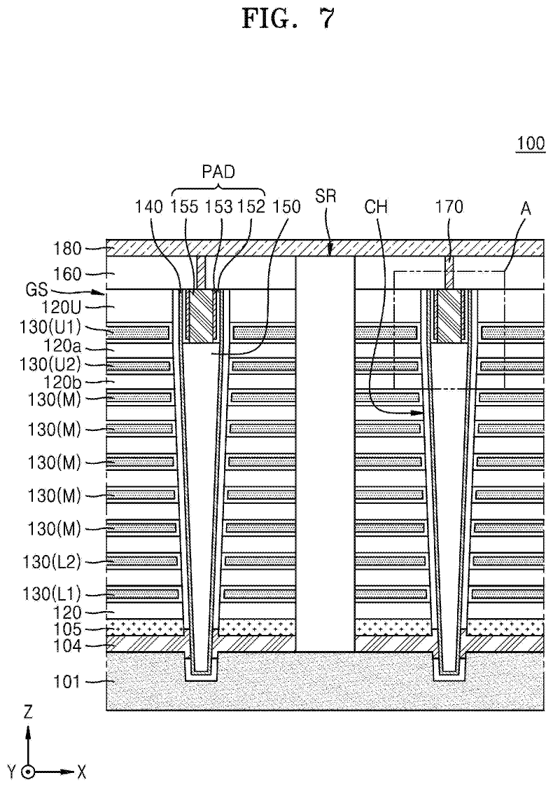

In the integrated circuit device 100, after the peripheral circuit region PERI has been manufactured, the substrate 101 of the memory cell region CELL may be formed thereon, and therefore, the memory cell region CELL may be manufactured. The substrate 101 may have a size (e.g., a surface area) that is identical to a size (e.g., a surface area) of the base substrate 201 or may be formed in a size (e.g., having a surface area) that is smaller than the size (e.g., a surface area) of the base substrate 201. The memory cell region CELL and the peripheral circuit region PERI may be connected to each other in a region that is not shown. For example, an end of each of the gate electrodes 130 in the second horizontal direction (the Y direction) may be electrically connected to the circuit devices 220. The form in which the memory cell region CELL and the peripheral circuit region PERI are vertically stacked may also be applied to embodiments shown in FIGS. 6 and 7 to be described below. To other configurations, the descriptions with reference to FIGS. 1 to 5 may be identically applied.

FIG. 6 is a cross-sectional view schematically illustrating the integrated circuit device 100 according to some embodiments of the inventive concept.

Referring to FIG. 6, the first upper gate electrode 130(U1) may include, as erase gate electrodes, a first erase gate electrode 130(U1a) and a second erase gate electrode 130(U1b). The second erase gate electrode 130(U1b) may be arranged under the first erase gate electrode 130(U1a). The first erase gate electrode 130(U1a) may be at an uppermost position among the gate electrodes 130. The second erase gate electrode 130(U1b) may be adjacent to (e.g., directly adjacent to) the first erase gate electrode 130(U1a) in the vertical direction (the Z direction) and may be at a second-highest position among the gate electrodes 130.

In some embodiments, the first erase gate electrode 130(U1a) may overlap the pad structure PAD in the first horizontal direction (the X direction). A side surface of the first erase gate electrode 130(U1a) may face the side surface of the pad structure PAD. In some embodiments, (although not illustrated in FIG. 6) the first erase gate electrode 130(U1a) and the second erase gate electrode 130(U1b) may overlap the pad structure PAD in the first horizontal direction (the X direction). In some embodiments, (although not illustrated in FIG. 6) side surfaces of the first erase gate electrode 130(U1a) and the second erase gate electrode 130(U1b) may face the side surface of the pad structure PAD.

In some embodiments, a level of a height of a lower surface of the pad structure PAD may be lower than or equal to a level of a height of a lower surface of the first erase gate electrode 130(U1a) and equal to or higher than a level of a height of an upper surface of the second erase gate electrode 130(U1b). Particularly, a level of a height of a lower surface of the pad pattern 155 may be lower than or equal to the level of the height of the lower surface of the first erase gate electrode 130(U1a) and equal to or higher than the level of the height of the upper surface of the second erase gate electrode 130(U1b).

In some embodiments, a thickness in the vertical direction (the Z direction) of a first interlayer insulating layer 120al disposed between the first erase gate electrode 130(U1a) and the second erase gate electrode 130(U1b) may be different from thicknesses in the vertical direction of other interlayer insulating layers 120a2, 120b, and 120. The other interlayer insulating layers 120a2, 120b, and 120 may refer to interlayer insulating layers lower than the first interlayer insulating layer 120al in the vertical direction among the plurality of interlayer insulating layers 120. Particularly, a thickness in the vertical direction (the Z direction) of a first interlayer insulating layer 120al may be greater than the thicknesses in the vertical direction (the Z direction) of other interlayer insulating layers 120a2, 120b, and 120. For example, the thickness in the vertical direction (the Z direction) of the first interlayer insulating layer 120a may be in a range from about 380 Å to about 500 Å.

In some embodiments, thicknesses in the vertical direction of the first erase gate electrode 130(U1a) and/or the second erase gate electrode 130(U1b) may be greater than other gate electrodes 130(U2), 130(M), 130(L1), or 130(L2) from among the gate electrodes 130.

FIG. 7 is a cross-sectional view schematically illustrating the integrated circuit device 100 according to some embodiments of the inventive concept.

Referring to FIG. 7, the thickness in the vertical direction (the Z direction) of the first upper gate electrode 130(U1) may be greater than the thicknesses in the vertical direction (the Z direction) of the other gate electrodes 130(U2), 130(M), 130(L1), and 130(L2) among the plurality of the gate electrodes 130. For example, the other gate electrodes 130(U2), 130(M), 130(L1), and 130(L2) may be lower than the first upper gated electrode 130(U1) in the vertical direction.

Referring to FIGS. 3 to 7, by forming the thickness in the vertical direction (the Z direction) of the first upper gate electrode 130(U1) and/or the thickness in the vertical direction (the Z direction) of the first interlayer insulating layer 120a in a great height, a distance between an upper surface of the stack structure GS and an upper surface of the first upper gate electrode 130(U1) may be formed shorter. That is, a thickness in the vertical direction (the Z direction) of the uppermost interlayer insulating layer 120U may be formed less (thinner) compared with the thickness of the uppermost interlayer insulating layer 120U in the Comparative Example. For example, a distance between the upper surface of the stack structure GS and the upper surface of the first upper gate electrode 130(U1) may be formed to be about 550 Å.

In the integrated circuit device 100 according to some embodiments of the inventive concept, as the distance between an upper portion of the stack structure GS and the upper surface of the first upper gate electrode 130(U1) is formed shorter, an amount of recesses required for forming the pad structure PAD may be reduced. Accordingly, a process for forming the pad structure PAD may be simplified.

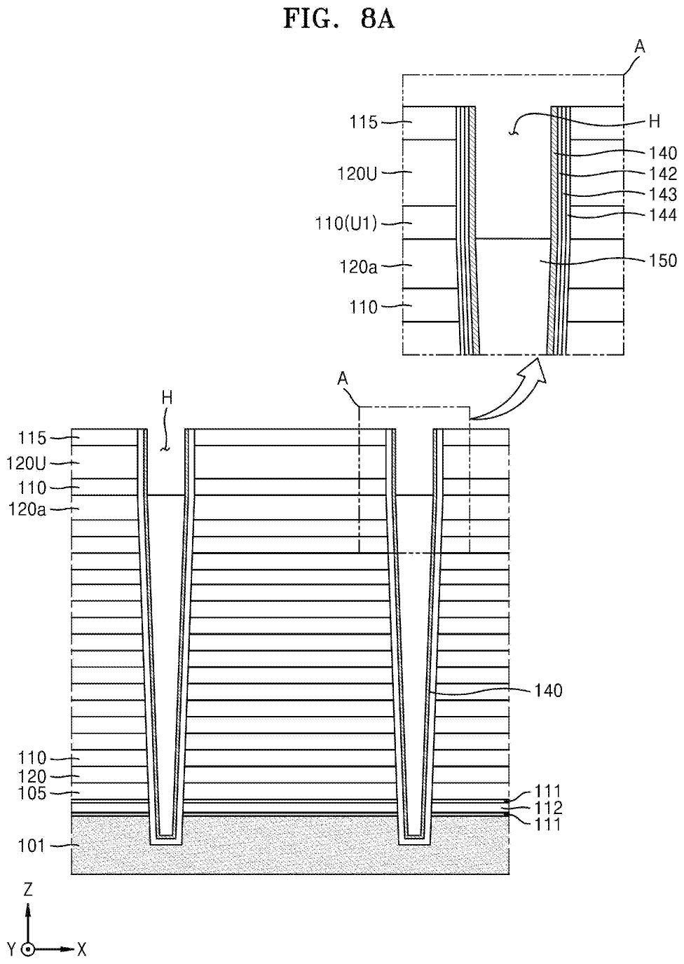

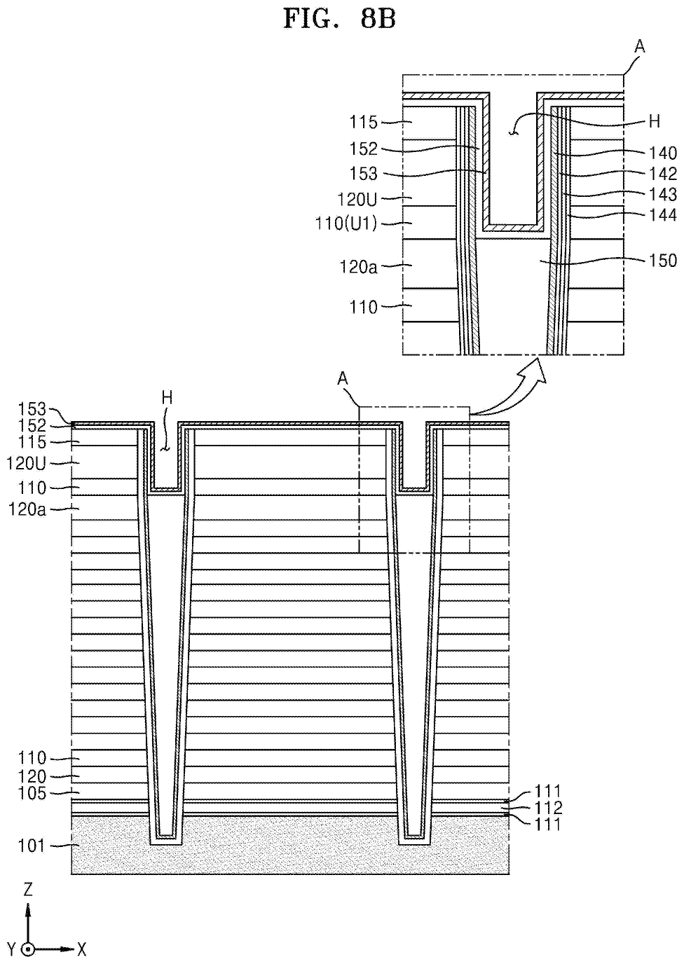

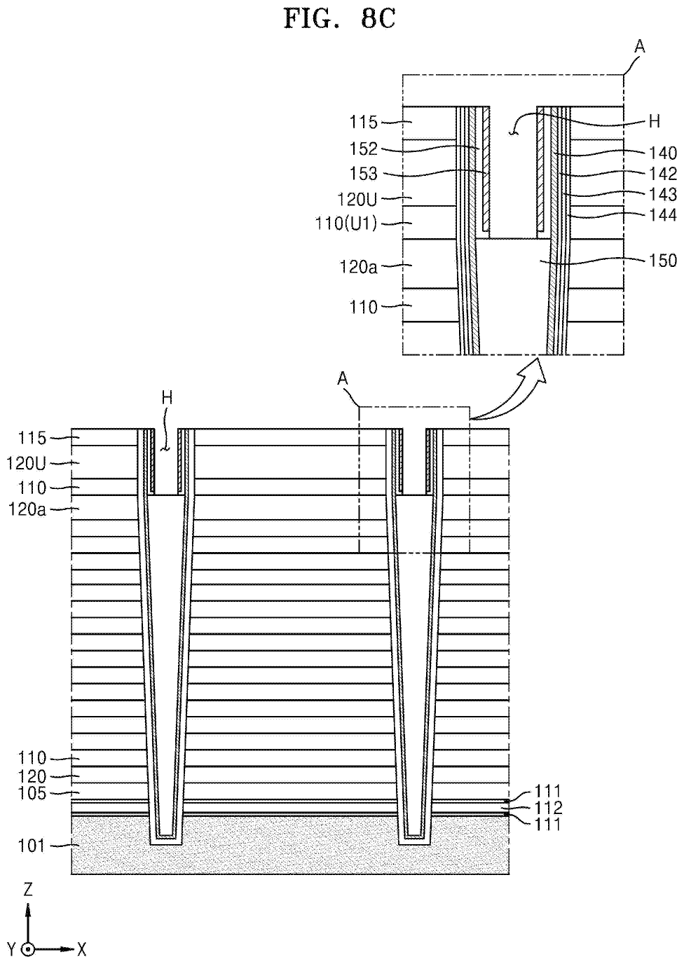

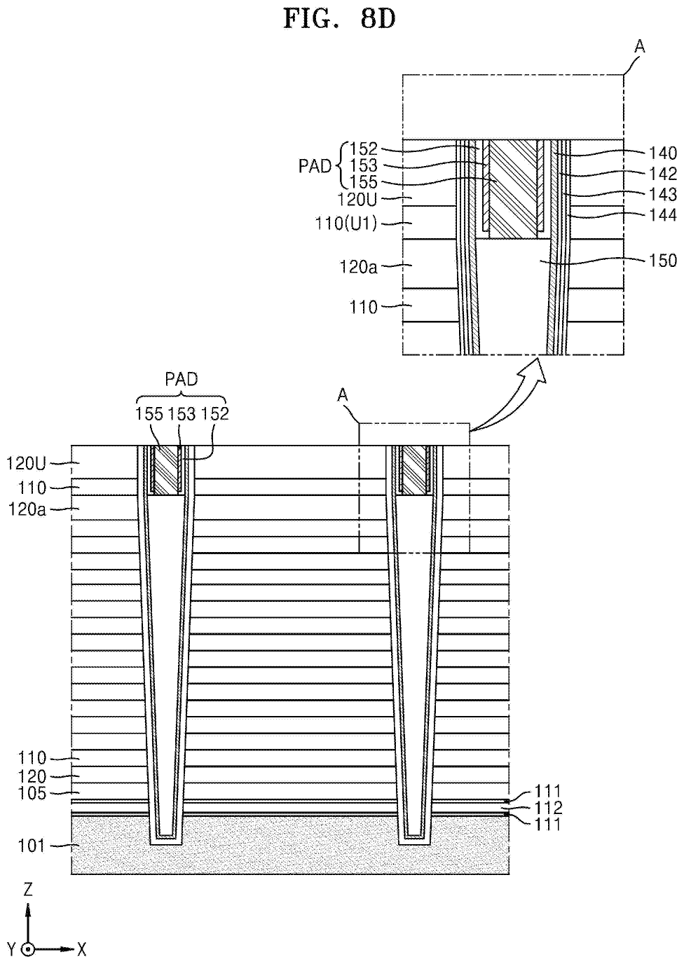

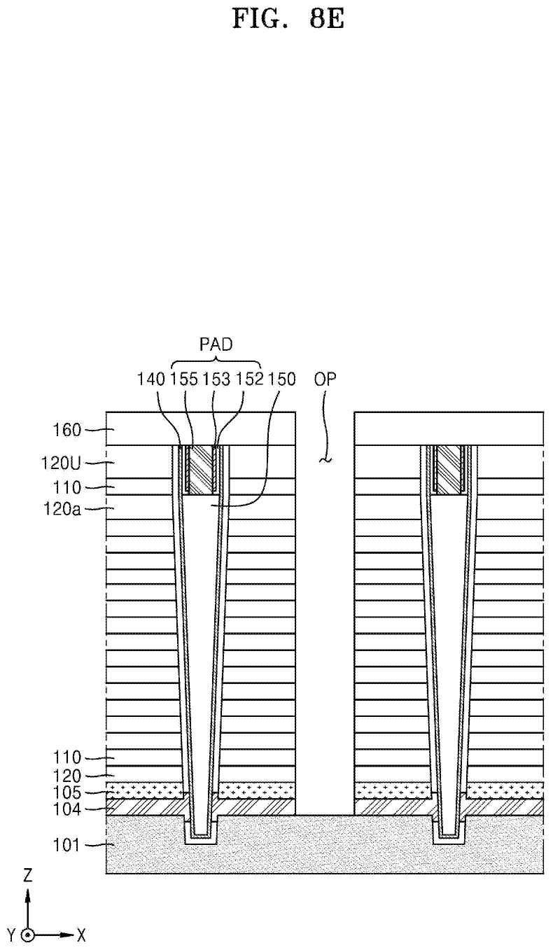

FIGS. 8A to 8E are cross-sectional views for describing a method of manufacturing the integrated circuit device 100, according to some embodiments of the inventive concept.

Referring to FIG. 8A, first source sacrificial layers 111, a second source sacrificial layer 112, and the second conductive pattern 105 may be formed on the substrate 101 and horizontal sacrificial layers 110 and interlayer insulating layers 120 may be alternately stacked, and by doing so, a preliminary stack structure may be formed. A channel hole extending in (e.g., penetrating) the preliminary stack structure may be formed and the blocking layer 144, the charge storage layer 143, the tunneling layer 142, the channel layer 140, and the core pattern 150 may be sequentially buried in the channel hole. For example, the blocking layer 144, the charge storage layer 143, the tunneling layer 142, and the channel layer 140 may be sequentially stacked on an inner side surface and a lower surface of the channel hole, and a remaining portion of the channel hold may be filled with the core pattern 150. An upper portion of the core pattern 150 may be partially removed, and by doing so, a recess region H may be formed.

First, the first source sacrificial layers 111 and the second source sacrificial layer 112 may include different materials and be stacked on the substrate 101 such that the first source sacrificial layers 111 may be arranged on and under the second source sacrificial layer 112. The first source sacrificial layers 111 and the second source sacrificial layer 112 may be replaced by the first conductive pattern 104 shown in FIG. 3 through the following processes. For example, the first source sacrificial layers 111 may include a same material as the interlayer insulating layers 120, and the second source sacrificial layer 112 may include a same material as the horizontal sacrificial layers 110. The second conductive pattern 105 may be arranged on the first source sacrificial layers 111 and the second source sacrificial layer 112.

Next, the preliminary stack structure may be formed by alternately stacking the horizontal sacrificial layers 110 and the interlayer insulating layers 120 on the second conductive pattern 105.

The horizontal sacrificial layers 110 may include layers replaced with the gate electrodes 130 through the following processes. The horizontal sacrificial layers 110 may be formed of a material that is different from the material of the interlayer insulating layers 120. For example, the interlayer insulating layers 120 may be formed of silicon oxide, the horizontal sacrificial layers 110 may be formed of a material selected from among silicon, silicon carbide, and silicon nitride, i.e., a material that is different from the material of the interlayer insulating layer 120. In some embodiments, a thickness of some of the interlayer insulating layers 120 in the vertical direction may be different from a thickness of other interlayer insulating layers 120 in the vertical direction. For example, the lowermost interlayer insulating layer 120L may be formed in a relatively smaller thickness, and the uppermost interlayer insulating layer 120U may be formed in a relatively greater thickness. For example, a thickness of the uppermost interlayer insulating layer 120U may be greater (thicker) than a thickness of an interlayer insulating layer from among the interlayer insulating layers 120, which is between the uppermost interlayer insulating layer 120U and the lowermost interlayer insulating layer 120L. A thickness of the lowermost interlayer insulating layer 120L may be smaller (thinner) than a thickness of an interlayer insulating layer from among the interlayer insulating layers 120, which is between the uppermost interlayer insulating layer 120U and the lowermost interlayer insulating layer 120L. The thicknesses of the interlayer insulating layers 120 and the horizontal sacrificial layers 110 and the numbers of films included therein may be variously modified from the illustration. A stop layer 115 may be formed at the uppermost portion of the interlayer insulating layers 120 (e.g., on the uppermost interlayer insulating layer 120U).

In addition, the thickness in the vertical direction (the Z direction) of the first interlayer insulating layers 120a may be formed greater than the thickness in the vertical direction (the Z direction) of other interlayer insulating layers 120. For example, the thickness in the vertical direction (the Z direction) of the first interlayer insulating layer 120a may be in a range from about 380 Å to about 500 Å.

Next, channel holes may be formed in a region corresponding to the channel structures CH shown in FIG. 3. The channel holes may be formed by isotropically etching the preliminary stack structure and may be formed in the form of a hole. Due to a height of the preliminary stack structure, sidewalls of the channel holes may be not perpendicular to the upper surface of the substrate 101. The channel holes may be formed to be recessed in a portion of the substrate 101.

The blocking layer 144, the charge storage layer 143, the tunneling layer 142, the channel layer 140, and the core pattern 150 may be sequentially buried in the channel holes. The channel layer 140, the tunneling layer 142, the charge storage layer 143, and the blocking layer 144 may be formed in a uniform thickness through atomic layer deposition (ALD) process or chemical vapor deposition (CVD) process. The core pattern 150 may be formed to fill an inner portion of the channel layer 140 and may include an insulating material.

Next, the recess region H may be formed by partially removing the upper portion of the core pattern 150. A portion of the core pattern 150 may be removed through an etching process. In this case, a degree to which the core pattern 150 is etched may be adjusted such that the upper surface of the core pattern 150 may overlap the uppermost horizontal sacrificial layer 110(U1) in the first horizontal direction (the X direction). That is, a side surface of the recess region H and a side surface of the uppermost horizontal sacrificial layer 110U1 may face each other.

By forming the thickness in the vertical direction (the Z direction) of the first interlayer insulating layer 120a in a greater thickness, a distance between the upper surface of the preliminary stack structure, which corresponds to the stack structure GS to be formed by following processes, and the upper surface of the first upper gate electrode 130(U1) may be formed shorter. As the distance between the upper surface of the preliminary stack structure and the upper surface of the first upper gate electrode 130(U1) is formed shorter, the removal of the recess region H may be reduced as much as possible.

Referring to FIG. 8B, the second pad layer 152 and the first pad layer 153 may be sequentially stacked in the recess region H.

The second pad layer 152 and the first pad layer 153 may be sequentially deposited along a surface in the recess region H. In some embodiments, the second pad layer 152 may be deposited in a thickness that is greater than a thickness of the first pad layer 153. The second pad layer 152 may include a semiconductor material such as polycrystalline silicon, and the semiconductor material may include an undoped material. In some embodiments, the first pad layer 153 may be deposited in a thickness that is less than the thickness of the second pad layer 152. The first pad layer 153 may include a semiconductor material such as polycrystalline silicon, and the semiconductor material may include a p-type impurity, e.g., boron (B). In some embodiments, when the first pad layer 153 is doped with B, the concentration of B may be in a range from about 1×10²⁰/cm³ to about 1.5×10²⁰/cm³.

Referring to FIG. 8C, the first pad layer 153 and the second pad layer 152 may be partially removed. The first pad layer 153 and the second pad layer 152, disposed under the recess region H, may be removed through an etching process, e.g., an anisotropic etching process. For example, a portion of each of the first pad layer 153 and the second pad layer 152 on a lower surface of the recess region H may be removed. As the first pad layer 153 and the second pad layer 152 are partially etched, the upper surface of the core pattern 150 may be at least partially exposed in the recess region H.

Referring to FIG. 8D, in the recess region H, after forming the pad pattern 155 filling an inner portion of the first pad layer 153, a planarization process may be performed to form the pad structure PAD including the pad pattern 155, the first pad layer 153, and the second pad layer 152.

The pad pattern 155 may include a semiconductor material such as polycrystalline silicon, and the semiconductor material may include an n-type impurity, e.g., phosphorous (P) and arsenic (As). In some embodiments, when the pad pattern 155 is doped with P or As, the concentration of P or As may be in a range from about 2×10²⁰/cm³ to about 3×10²⁰/cm³.

According to some embodiments, referring to FIGS. 3 to 7, as the distance between the upper surface of the stack structure GS and the upper surface of the first upper gate electrode 130(U1) is reduced, the process of forming the pad structure PAD may be simplified as much as possible.

In some embodiments, the planarization process may include chemical mechanical polishing (CMP). During or after the planarization process, the stop layer 115 may be removed.

Referring to FIG. 8E, the upper insulating layer 160 may be formed on the uppermost interlayer insulating layer 120U and the pad structure PAD. After forming an opening OP separating the upper insulating layer 160 and the preliminary stack structure by a certain distance and extending in (e.g., penetrating) the upper insulating layer 160 and the preliminary stack structure, and after removing the first source sacrificial layers 111 and the second source sacrificial layer 112 through the opening OP, the first conductive pattern 104 may be formed.

The opening OP may be formed in the form of a trench extending in the second horizontal direction (the Y direction) and may be formed in a region where the separation region SR shown in FIG. 3 is arranged.

In some embodiments, before removing the first source sacrificial layers 111 and the second source sacrificial layer 112, a spacer layer may be formed on a sidewall of the opening OP to protect the horizontal sacrificial layers 110. After the second source sacrificial layers 112 is first removed through the opening OP, the first source sacrificial layers 111 may be removed. The first source sacrificial layers 111 and the second source sacrificial layer 112 may be removed through, for example, an isotropic etching process. In a process of removing the first source sacrificial layers 111, the tunneling layer 142, the charge storage layer 143, and the blocking layer 144 shown in FIG. 4, which are exposed in a region from which the second source sacrificial layer 112 has been removed, may be partially removed together. After the first conductive pattern 104 is formed by depositing a conductive material in a region from which the first source sacrificial layers 111 and the second source sacrificial layer 112 have been removed, the spacer layer may be removed. The first conductive pattern 104 may directly contact the channel layer 140 in the region from which the tunneling layer 142, the charge storage layer 143, and the blocking layer 144 have been removed.

Next, referring again to FIG. 3, after removing the horizontal sacrificial layers 110 exposed through the opening OP, the gate electrodes 130 may be formed by disposing (e.g., burying) a conductive material in a region from which the horizontal sacrificial layers 110 have been removed, and the opening OP may be at least partially filled with an insulating material, and thus, the separation region SR may be formed. Thereafter, the contact plugs 170 extending in (e.g., penetrating) the upper insulating layer 160 and the bit line 180 arranged on the contact plugs 170 may be formed.

After the forming of the first conductive pattern 104, the spacer layers may be removed from the opening OP. The gate electrodes 130 may include metal, polycrystalline silicon, or a metal silicide material. After forming the gate electrodes 130, the opening OP may be filled with the insulating material to form the separation region SR.

Next, the contact plugs 170 extending in (e.g., penetrating) the upper insulating layer 160 and electrically connected to the pad structure PAD may be formed. The contact plugs 170 may be formed by removing a portion of the upper insulating layer 160 through etching and filling a region, from which the portion of the upper insulating layer 160 has been removed, with the conductive material. The bit line 180 may be formed of the conductive material.

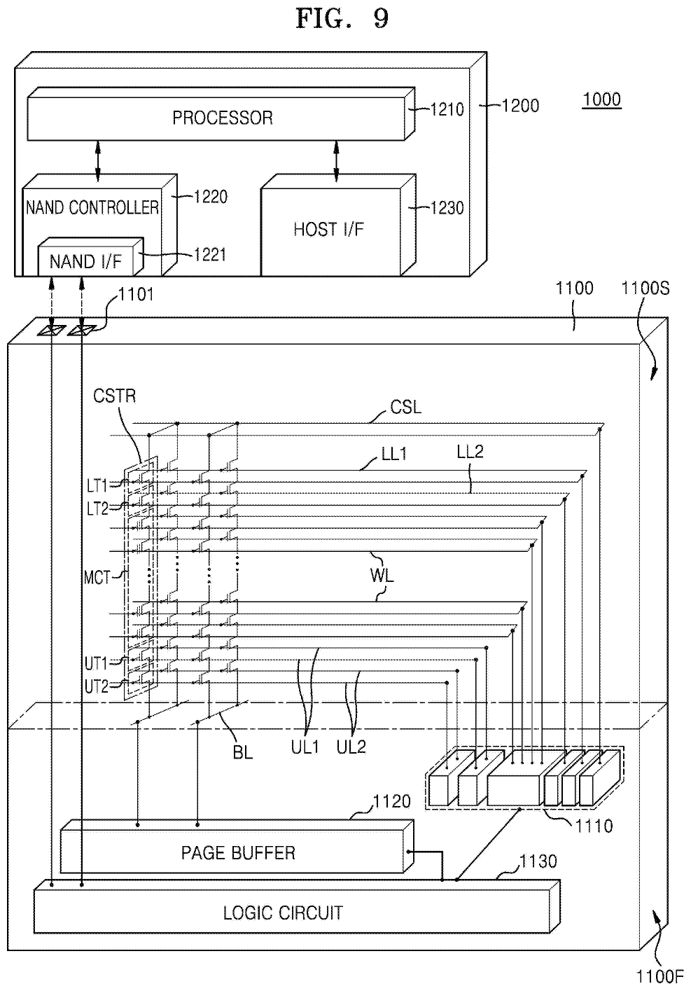

FIG. 9 is a diagram schematically illustrating a data storage system 1000 including the integrated circuit device 100 according to some embodiments of the inventive concept.

Referring to FIG. 9, the data storage system 1000 may include one or more memory devices 1100 and a memory controller 1200 electrically connected to the one or more memory devices 1100. The data storage system 1000 may include, for example, a solid state drive (SSD) device including the one or more memory devices 1100, a universal serial bus (USB), a computing system, a medical device, or a communication device.

The memory device 1100 may include a nonvolatile memory device, and for example, the memory device 1100 may include a NAND flash memory device including the integrated circuit device 100 described above with reference to FIGS. 1 to 8E. The memory device 1100 may include a first structure 1100F and a second structure 1100S on the first structure 1100F. The first structure 1100F may include a peripheral circuit structure including a row decoder 1110, a page buffer 1120, and a logic circuit 1130.

The second structure 1100S may include a memory cell structure including the bit line BL, the common source line CSL, a plurality of word lines WL, a GIDL string selection line UL2 (e.g., corresponding to one of the GIDL string selection lines GIDL_SSL1, GIDL_SSL2, and GIDL_SSL3 in FIG. 2), a string selection line UL1 (e.g., corresponding to the string selection line SSL1 in FIG. 2), a GIDL ground selection line LL1 (e.g., corresponding to one of the GIDL ground selection lines GIDL_GSL1, GIDL_GSL2, and GIDL_GSL3 in FIG. 2), a ground selection line LL2 (e.g., corresponding to the ground selection line GSL in FIG. 2), and a plurality of memory cell strings CSTR between the bit line BL and the common source line CSL.

In the second structure 1100S, the plurality of memory cell strings CSTR may each include a GIDL ground selection transistor LT1 (e.g., corresponding to the GIDL ground selection transistor GIDL_GST in FIG. 2) adjacent to (e.g., directly adjacent to) the common source line CSL, a ground selection transistor LT2 (e.g., corresponding to the ground selection transistor GST in FIG. 2), a GIDL string selection transistor UT2 (e.g., corresponding to the GIDL_SST in FIG. 2) adjacent to (e.g., directly adjacent to) the bit line BL, a string selection transistor UT1 (e.g., corresponding to the string selection transistor SST in FIG. 2), and a plurality of memory cell transistors MCT arranged between the ground selection transistor LT2 and the string selection transistor UT1. The numbers of GIDL ground selection transistors LT1, ground selection transistors LT2, GIDL string selection transistors UT2, and string selection transistors UT1 may be variously modified according to some embodiments.

In some embodiments, the GIDL string selection line UL2 and the string selection line UL1 may be respectively connected to gate electrodes of the GIDL string selection transistor UT2 and the string selection transistor UT1. The word line WL may be connected to a gate electrode of the memory cell transistor MCT. The GIDL ground selection line LL1 and the ground selection line LL2 may be respectively connected to gate electrodes of the GIDL ground selection transistor LT1 and the ground selection transistor LT2.

The common source line CSL, the GIDL string selection line UL2, the string selection line UL1, the plurality of word lines WL, the GIDL ground selection line LL1, and the ground selection line LL2 may be connected to the row decoder 1110. The plurality of bit lines BL may be electrically connected to the page buffer 1120.

The memory device 1100 may communicate with the memory controller 1200 through an input/output pad 1101 electrically connected to the logic circuit 1130. The input/output pad 1101 may be electrically connected to the logic circuit 1130.

The memory controller 1200 may include a processor 1210, a NAND controller 1220, and a host interface 1230. In some embodiments, the data storage system 1000 may include a plurality of memory devices 1100, and in this case, the memory controller 1200 may be configured to control the plurality of memory devices 1100.

The processor 1210 may be configured to control general operations of the data storage system 1000 including the memory controller 1200. The processor 1210 may be configured to operate according to certain firmware and control the NAND controller 1220 to access the memory device 1100. The NAND controller 1220 may include a NAND interface 1221 configured to process communication with the memory device 1100. Through the NAND interface 1221, a control instruction to control the memory device 1100, data to be written to the plurality of memory cell transistors MCT of the memory device 1100, and data to be read from the plurality of memory cell transistors MCT of the memory device 1100 may be transmitted. The host interface 1230 may be configured to provide a communication function between the data storage system 1000 and an external host. When a control command is received from the external host through the host interface 1230, the processor 1210 may be configured to control the memory device 1100 in response to the control command.

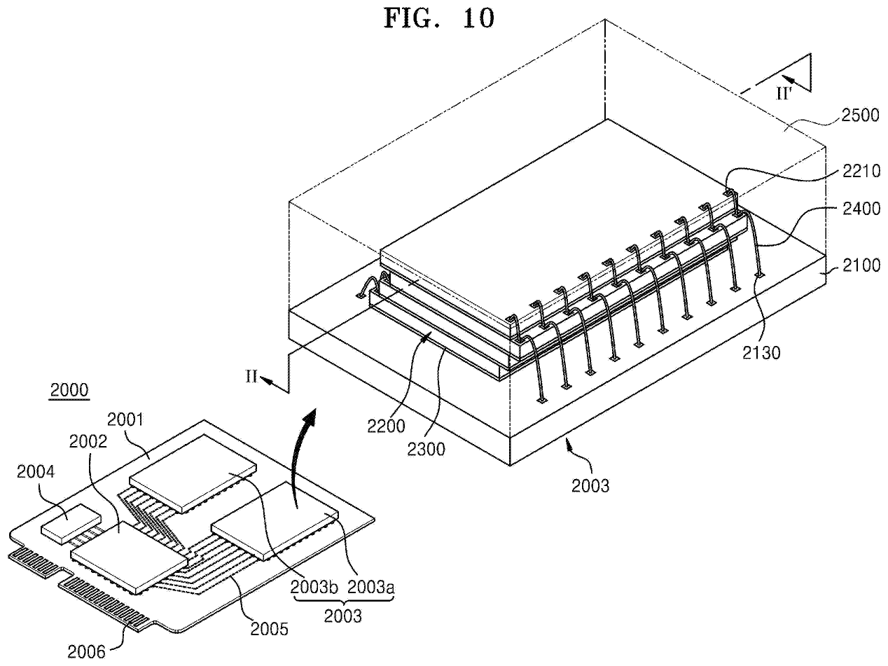

FIG. 10 is a perspective view schematically illustrating a data storage system 2000 including an integrated circuit device (e.g., the integrated circuit device 100) according to some embodiments.

Referring to FIG. 10, the data storage system 2000 according to some example embodiments may include a main substrate 2001, a memory controller 2002 mounted on the main substrate 2001, at least one semiconductor package 2003, and dynamic random access memory (DRAM) 2004. The semiconductor package 2003 and the DRAM 2004 may be connected to the memory controller 2002 through a plurality of wiring patterns 2005 formed on the main substrate 2001.

The main substrate 2001 may include a connector 2006 including a plurality of pins combined to the external host. The number and arrangement of the plurality of pins in the connector 2006 may vary according to a communication interface between the data storage system 2000 and the external host. In some embodiments, the data storage system 2000 may be configured to communicate with the external host according to any one of interfaces, e.g., universal serial bus (USB), peripheral component interconnect express (PCI-Express), serial advanced technology attachment (SATA), an M-Phy for universal flash storage (UFS), and the like. In some embodiments, the data storage system 2000 may be configured to operate by power provided from the external host through the connector 2006. The data storage system 2000 may further include a power management integrated circuit (PMIC) configured to distribute the power, which is provided from the external host, to the memory controller 2002 and the semiconductor package 2003.

The memory controller 2002 may be configured to write data to the semiconductor package 2003, read data from the semiconductor package 2003, or improve an operation rate of the data storage system 2000.

The DRAM 2004 may include a buffer memory configured to reduce a difference between rates of the semiconductor package 2003, which is a data storage space, and the external host. The DRAM 2004 included in the data storage system 2000 may also be configured to operate as a cache memory and may also provide a space for temporally storing data in an operation of controlling the semiconductor package 2003. When the DRAM 2004 is included in the data storage system 2000, the memory controller 2002 may further include a DRAM controller configured to control the DRAM 2004, in addition to the NAND controller configured to control the semiconductor package 2003.

The semiconductor package 2003 may include a first semiconductor package 2003a and a second semiconductor package 2003b apart from each other. The first semiconductor package 2003a and the second semiconductor package 2003b may each include a semiconductor package including a plurality of semiconductor chips 2200. Each of the first semiconductor package 2003a and the second semiconductor package 200b may include a package substrate 2100, the plurality of semiconductor chips 2200 on the package substrate 2100, an adhesion layer 2300 arranged at a lower surface of each of the plurality of semiconductor chips 2200, a connection structure 2400 to electrically connect the plurality of semiconductor chip 2200 to the package substrate 2100, and a molding layer 2500 on (e.g., covering) the plurality of semiconductor chips 2200 and the connection structure 2400 on the package substrate 2100.

The package substrate 2100 may include a printed circuit board including a plurality of package upper pads 2130. The plurality of semiconductor chips 2200 may each include an input/output pad 2210. The input/output pad 2210 may correspond to the input/output pad 1101 shown in FIG. 9. The plurality of semiconductor chips 2200 may each include the integrated circuit device 100 described with reference to FIGS. 1 to 8E.

In some embodiments, the connection structure 2400 may include a bonding wire electrically connecting the input/output pad 2210 and the package upper pad 2130. Accordingly, in the first semiconductor package 2003a and the second semiconductor package 2003b, the plurality of semiconductor chips 2200 may be connected to each other in a bonding wire scheme, and may also be electrically connected to the package upper pad 2130 of the package substrate 2100. In some embodiments, in the first semiconductor package 2003a and the second semiconductor package 2003b, the plurality of semiconductor chips 2200 may be electrically connected to each other through a connection structure including a through silicon via (TSV), instead of the connection structure 2400 in which the bonding wire scheme is used.

In example embodiments, the memory controller 2002 and the plurality of semiconductor chips 2200 may be included in one package. In some embodiments, the memory controller 2002 and the plurality of semiconductor chips 2200 may be mounted on a separate interposer substrate different from the main substrate 2001, and the memory controller 2002 may be connected to the plurality of semiconductor chips 2200 through wirings formed on the interposer substrate.

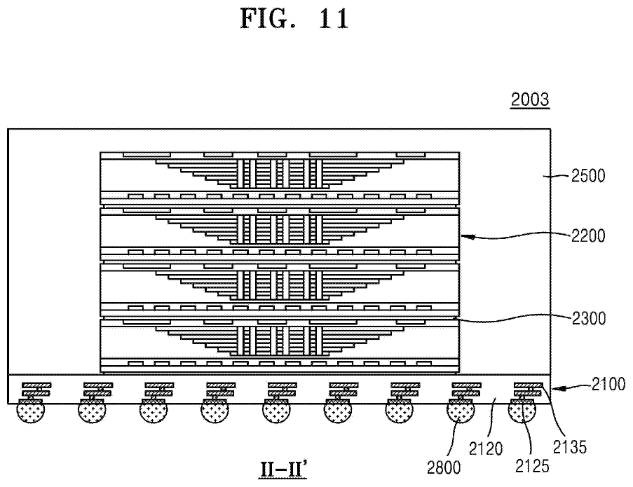

FIG. 11 is a cross-sectional view schematically illustrating the semiconductor packages 2003 according to some embodiments of the inventive concept.

Referring to FIG. 11, in the semiconductor package 2003, the package substrate 2100 may include a printed circuit board. The package substrate 2100 may include a package substrate body 2120, the plurality of package upper pads 2130 (see FIG. 10) arranged on an upper surface of the package substrate body 2120, a plurality of lower pads 2125 arranged on a lower surface of the package substrate body 2120 or exposed through the package substrate body 2120, and a plurality of internal wirings 2135 electrically connecting the plurality of package upper pads 2130 (see FIG. 10) and the plurality of lower pads 2125 in the package substrate body 2120. As shown in FIG. 11, the plurality of package upper pads 2130 may be electrically connected to the plurality of connection structures 2400. As shown in FIG. 11, the plurality of lower pads 2125 may be connected to a plurality of wiring patterns 2005 on the main substrate 2001 of the data storage system 2000 shown in FIG. 10, through a plurality of conductive bumps 2800. Each of the plurality of semiconductor chips 2200 may include the integrated circuit device 100 described with reference to FIGS. 1 to 8E.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a substrate;
a stack structure comprising interlayer insulating layers and gate electrodes stacked alternately with the interlayer insulating layers on the substrate;
a channel structure comprising a core pattern, a pad structure on the core pattern, and a channel layer on a side surface of the core pattern and a side surface of the pad structure, wherein the channel structure is in the stack structure;
a plug on the channel structure; and
a bit line on the plug,
wherein the gate electrodes comprise a first upper gate electrode at a highest position among the gate electrodes relative to the substrate and a second upper gate electrode at a second-highest position among the gate electrodes relative to the substrate,
the second upper gate electrode is directly adjacent to the first upper gate electrode in a vertical direction perpendicular to an upper surface of the substrate,
the interlayer insulating layers comprises a first interlayer insulating layer that is between the first upper gate electrode and the second upper gate electrode and has a first thickness in the vertical direction,
the first thickness is different from a second thickness of a second interlayer insulating layer of the interlayer insulating layers in the vertical direction, and
a lower surface of the pad structure is distant from the substrate by a first distance, a lower surface of the first upper gate electrode is distant from the substrate by a second distance that is longer than or equal to the first distance, and an upper surface of the second upper gate electrode is distant from the substrate by a third distance that is shorter than or equal to the first distance.

2. The integrated circuit device of claim 1, wherein the first thickness is greater than the second thickness.

3. The integrated circuit device of claim 1, wherein the first thickness is in a range from about 380 angstroms (Å) to about 500 Å.

4. The integrated circuit device of claim 1, wherein at least one of the first upper gate electrode and the second upper gate electrode has a third thickness in the vertical direction different from a fourth thickness of one gate electrode of the gate electrodes in the vertical direction.

5. The integrated circuit device of claim 1, wherein the first upper gate electrode and the second upper gate electrode comprise erase gate electrodes.

6. The integrated circuit device of claim 1, wherein the first upper gate electrode has a third thickness in the vertical direction,
wherein on electrode of the gate electrodes has a fourth thickness in the vertical direction, and
a sum of the third thickness and the first thickness and a sum of the fourth thickness and the second thickness.

7. The integrated circuit device of claim 1, wherein the pad structure comprises:
a pad pattern;
a first pad layer between the channel layer and the pad pattern; and
a second pad layer comprising a first portion and a second portion, wherein the first portion is between the channel layer and the first pad layer, and the second portion is between the first pad layer and the core pattern.

8. The integrated circuit device of claim 7,
wherein the pad pattern has a first conductive type, and
the first pad layer has a second conductive type that is different from the first conductive type.

9. The integrated circuit device of claim 7, wherein a lower surface of the pad pattern is distant from the substrate by a fourth distance, the lower surface of the first upper gate electrode is distant from the substrate by a fifth distance that is longer than or equal to the fourth distance, and the upper surface of the second upper gate electrode is distant from the substrate by a sixth distance that is shorter than or equal to the fourth distance.

10. The integrated circuit device of claim 7, wherein at least a portion of the first upper gate electrode overlaps the pad structure in a first horizontal direction.

11. An integrated circuit device comprising:
a substrate;
a stack structure comprising interlayer insulating layers and gate electrodes stacked alternately with the interlayer insulating layers on the substrate;
a channel structure in the stack structure;
a plug on the channel structure; and
a bit line on the plug,
wherein the channel structure comprises a core pattern, a pad structure on the core pattern, and a channel layer on a side surface of the core pattern and a side surface of the pad structure,
a first upper gate electrode at a highest position among the gate electrodes relative to the substrate comprises an erase gate electrode,
a first thickness in a vertical direction of a first interlayer insulating layer of the interlayer insulating layers is different from a second thickness in the vertical direction of a second interlayer insulating layer of the interlayer insulating layers,
the first interlayer insulating layer is between the first upper gate electrode and the second interlayer insulating layer, and
the vertical direction is perpendicular to an upper surface of the substrate.

12. The integrated circuit device of claim 11, wherein the first thickness is greater than the second thickness.

13. The integrated circuit device of claim 11, wherein at least a portion of the first upper gate electrode overlaps the pad structure in a first horizontal direction perpendicular to the vertical direction.

14. The integrated circuit device of claim 11, wherein a third thickness of the first upper gate electrode in the vertical direction is different from a fourth thickness one gate electrode of the gate electrodes in the vertical direction.

15. The integrated circuit device of claim 11, wherein the pad structure comprises a pad pattern, a first pad layer between the channel layer and the pad pattern, and a second pad layer comprising a first portion and a second portion,
wherein the first portion is between the channel layer and the first pad layer, and
wherein the second portion is between the first pad layer and the core pattern.

16. The integrated circuit device of claim 15,
wherein the pad pattern has a first conductive type, and
the first pad layer has a second conductive type that is different from the first conductive type.

17. An integrated circuit device comprising:
a first substrate;
circuit devices on the first substrate;
a second substrate on the circuit devices;
a stack structure comprising interlayer insulating layers and gate electrodes stacked alternately with the interlayer insulating layers on the second substrate in a vertical direction perpendicular to an upper surface of the second substrate; and
a channel structure in the stack structure, the channel structure comprising a channel layer, a core pattern on a side surface of the channel layer, and a pad structure on the core pattern,
wherein the gate electrodes comprise a first upper gate electrode at a highest position among the gate electrodes relative to the second substrate and a second upper gate electrode at a second-highest position among the gate electrodes relative to the second substrate,
a first thickness of a first interlayer insulating layer of the interlayer insulating layers in the vertical direction is different from a second thickness of a second interlayer insulating layer of the interlayer insulating layers in the vertical direction,
the first interlayer insulating layer is between the first upper gate electrode and the second upper gate electrode, and
a lower surface of the pad structure is distant from the second substrate by a first distance, a lower surface of the first upper gate electrode is distant from the second substrate by a second distance that is longer than or equal to the first distance, and an upper surface of the second upper gate electrode is distant from the second substrate by a third distance that is shorter than or equal to the first distance.

18. The integrated circuit device of claim 17, wherein the first upper gate electrode and the second upper gate electrode comprise erase gate electrodes.

19. The integrated circuit device of claim 17, wherein the first thickness is greater than the second thickness.

20. The integrated circuit device of claim 17, wherein at least a portion of the first upper gate electrode overlaps the pad structure in a first horizontal direction perpendicular to the vertical direction.
